(19) United States
(12) Patent Application Publication
(10) Pub. No.: US 2023/0227994 A1
(43) Pub. Date: Jul. 20, 2023

(54) INK COMPOSITION FOR ELECTROPHORESIS DEVICE AND DISPLAY DEVICE USING SAME

(71) Applicant: SAMSUNG SDI CO., LTD., Yongin-si, Gyeonggi-do (KR)

(72) Inventors: Jinsuop YOUN, Suwon-si (KR); Dong Wan RYU, Suwon-si (KR); Misun KIM, Suwon-si (KR); Young Min KIM, Suwon-si (KR); Janghyuk KIM, Suwon-si (KR); Young Woo PARK, Suwon-si (KR); Chuljin PARK, Suwon-si (KR); Jiyoung JEONG, Suwon-si (KR); Eun Sun YU, Suwon-si (KR)

(21) Appl. No.: 18/002,426

(22) PCT Filed: May 21, 2021
(86) PCT No.: PCT/KR2021/006339

§ 371 Date: Dec. 19, 2022

(30) Foreign Application Priority Data
Oct. 30, 2020 (KR) 10-2020-0143749

(51) Int. Cl. C25D 15/00; C25D 13/02; C25D 13/08

(52) U.S. Cl. CPC C25D 15/00; C25D 13/02; C25D 13/08

(57) ABSTRACT

Disclosed are an ink composition for an electrophoresis apparatus including (A) a semiconductor nanorod; and (B) a compound represented by Chemical Formula 1, and a display device manufactured using the ink composition for an electrophoresis apparatus.

### BACKGROUND OF THE INVENTION

### (a) Field of the Invention

This disclosure relates to an ink composition for an electrophoresis apparatus and a display device using the same.

### (b) Description of the Related Art

LEDs have been actively developed since 1992 when Nakamura and others from Japanese Nichia Corp. succeeded in fusing a high-quality single crystal GaN nitride semiconductor by applying a low temperature GaN compound buffer layer. LED is a semiconductor device converting electric signals into light having wavelengths in a desired region by using characteristics of a compound semiconductor, which has a structure that an n-type semiconductor crystal in which a plurality of carriers is electrons and a p-type semiconductor crystal in which a plurality of carriers is holes are combined to each other.

This LED semiconductor has high light conversion efficiency and thus consumes very little energy and has a semipermanent life-span and also, is environmentally-friendly and thus called to be a revolution of light as a green material. Recently, high luminance red, orange, green, blue, and white LEDs have been developed with the development of compound semiconductor technology and are being applied in many fields such as traffic lights, mobile phones, car headlights, outdoor billboards, LCD BLU (back light unit), and indoor/outdoor lighting, which keeps being actively researched at home and abroad. Particularly, a GaN-based compound semiconductor having a wide bandgap is a material used to manufacture a LED semiconductor emitting light in green, blue, and ultraviolet (UV) regions, and since a blue LED device is used to manufacture a white LED device, lots of research is being made on this.

Among these series of studies, studies using ultra-small LED devices having a nano or micro unit size are being actively conducted, and in addition studies for utilizing these ultra-small LED devices in lighting and displays are being continuously made. In these studies, electrodes capable of applying power to the ultra-small LED devices, disposition of the electrodes for reducing a space occupied by the electrodes, a method of mounting the ultra-small LED devices on the disposed electrodes, and the like are continuously attracting attentions.

Among these, the method of mounting the ultra-small LED devices on the disposed electrodes still have difficulties of disposing and mounting the ultra-small LED devices on the electrodes as intended due to size limitations of the ultra-small LED devices. The reason is that the ultra-small LED devices are nano-scale or micro-scale and thus may not be one by one disposed and mounted by hand on a target electrode region.

Recently, as the demand for the nano-scale ultra-small LED devices is increasing, an attempt to manufacture a nano-scale GaN-based or InGaN-based compound semiconductor into a rod has been made, but there is a problem that dispersion stability of a nanorod itself in a solution (or a polymerizable compound) is greatly deteriorated. Until now, there has been no introduction of a technology of improving the dispersion stability of the semiconductor nanorod in a solution (or a polymerizable compound).

### SUMMARY OF THE INVENTION

An embodiment provides an ink composition for an electrophoresis apparatus (electrophoretic apparatus) having excellent dispersion stability and high dielectrophoretic properties of semiconductor nanorods.

Another embodiment provides a display device manufactured using the ink composition for an electrophoresis apparatus.

An embodiment provides an ink composition for an electrophoresis apparatus including (A) a semiconductor nanorod; and (B) a compound represented by Chemical Formula 1.

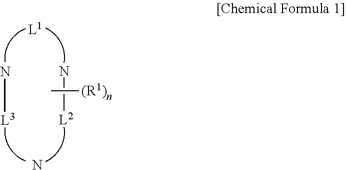

In Chemical Formula 1,

R¹ is a substituted or unsubstituted C1 to C20 alkyl group, a substituted or unsubstituted C1 to C20 alkoxy group, or a substituted or unsubstituted C6 to C20 aryl group,

L¹ to L³ are independently a substituted or unsubstituted C1 to C20 alkylene group, *—C(═O)—*, or *—C(R²)═*, wherein R² is a substituted or unsubstituted C1 to C10 alkyl group or a substituted or unsubstituted C1 to C10 alkoxy group, and

n is an integer of 0 to 3.

Chemical Formula 1 may be represented by Chemical Formula 2 or Chemical Formula 3.

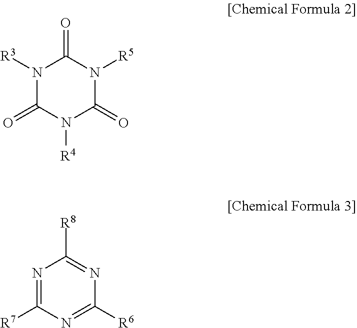

In Chemical Formula 2 and Chemical Formula 3,

R³ to R⁵ are independently a substituted or unsubstituted C1 to C20 alkyl group, and

R⁶ to R⁸ are independently a substituted or unsubstituted C1 to C20 alkoxy group.

In Chemical Formula 2, R³ to R⁵ may independently be a C1 to C20 alkyl group that is substituted or unsubstituted with a C2 to C10 alkenyl group.

In Chemical Formula 3, R⁶ to R⁸ may independently be a C1 to C20 alkoxy group that is substituted or unsubstituted with a C2 to C10 alkenyl group.

The compound represented by Chemical Formula 1 may include at least one selected from compounds represented by Chemical Formula 2-1, Chemical Formula 2-2, Chemical Formula 3-1, and Chemical Formula 3-2.

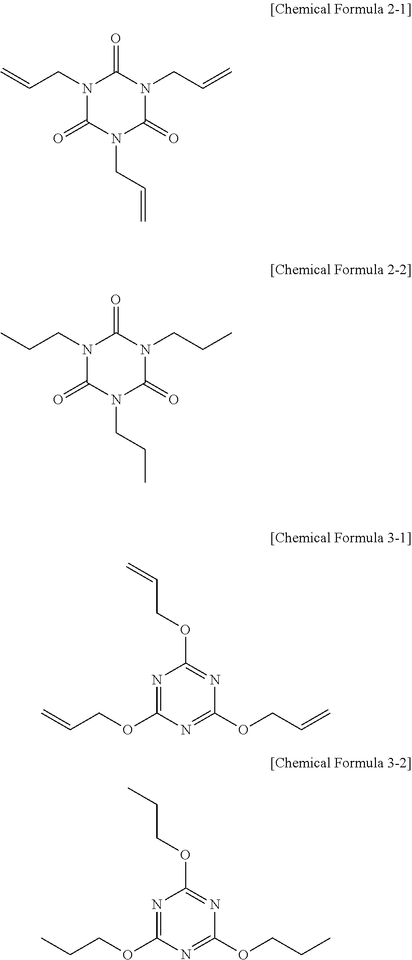

The compound represented by Chemical Formula 1 may have a viscosity of greater than or equal to 10 cps at 25° C.

The compound represented by Chemical Formula 1 may have a viscosity of 80 cps to 500 cps at 25° C.

The compound represented by Chemical Formula 1 may have a viscosity of 10 cps to 20 cps at 55° C.

The compound represented by Chemical Formula 1 may have a dielectric constant of 2 to 8.

The ink composition for an electrophoresis apparatus may further include a compound represented by Chemical Formula 4.

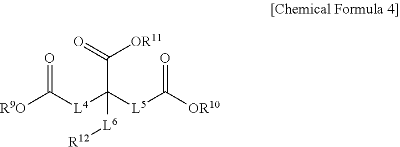

In Chemical Formula 4,

R⁹ to R¹¹ are independently a hydrogen atom or a C1 to C10 alkyl group,

R¹² is a hydrogen atom or *—C(═O)R¹³, wherein R¹³ is a C1 to C10 alkyl group,

L⁴ and L⁵ are independently a substituted or unsubstituted C1 to C20 alkylene group or a substituted or unsubstituted C6 to C20 arylene group, and

L⁶ is *—O—*, *—S—*, or *—NH—*.

The semiconductor nanorod may have a diameter of 300 nm to 900 nm.

The semiconductor nanorod may have a length of 3.5 μm to 5 μm.

The semiconductor nanorod may include a GaN-based compound, an InGaN-based compound, or a combination thereof.

The semiconductor nanorod may have a surface coated with a metal oxide.

The metal oxide may include alumina, silica, or a combination thereof.

The semiconductor nanorod may be included in an amount of 0.01 wt % to 10 wt % based on a total amount of the ink composition for an electrophoresis apparatus.

The ink composition for an electrophoresis apparatus may further include malonic acid; 3-amino-1,2-propanediol; a silane coupling agent; a leveling agent; a fluorine-based surfactant; or a combination thereof.

Another embodiment provides a display device manufactured using the ink composition for an electrophoresis apparatus.

Other embodiments of the present invention are included in the following detailed description.

By improving the dispersion stability of the semiconductor nanorod solution and realizing high dielectrophoretic properties, the semiconductor nanorod solution may be easily inkjetted or slit-coated to perform electrophoresis, thereby effectively producing a large-area panel.

### BRIEF DESCRIPTION OF THE DRAWING

FIG. 1 is an example of a cross-sectional view of a semiconductor nanorod used in an ink composition for an electrophoresis apparatus according to an embodiment.

### DETAILED DESCRIPTION OF THE EMBODIMENTS

Hereinafter, embodiments of the present invention are described in detail. However, these embodiments are exemplary, the present invention is not limited thereto and the present invention is defined by the scope of claims.

As used herein, when specific definition is not otherwise provided, the term “alkyl group” refers to a C1 to C20 alkyl group, the term “alkenyl group” refers to a C2 to C20 alkenyl group, the term “cycloalkenyl group” refers to a C3 to C20 cycloalkenyl group, the term “heterocycloalkenyl group” refers to a C3 to C20 heterocycloalkenyl group, the term “aryl group” refers to a C6 to C20 aryl group, the term “arylalkyl group” refers to a C6 to C20 arylalkyl group, the term “alkylene group” refers to a C1 to C20 alkylene group, the term “arylene group” refers to a C6 to C20 arylene group, the term “alkylarylene group” refers to a C6 to C20 alkylarylene group, the term “heteroarylene group” refers to a C3 to C20 heteroarylene group, and the term “alkoxylene group” refers to a C1 to C20 alkoxylene group.

As used herein, when specific definition is not otherwise provided, the term “substituted” refers to replacement of at least one hydrogen by a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid group or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, when specific definition is not otherwise provided, the term “hetero” refers to one including at least one heteroatom selected from N, O, S and P in a chemical formula.

As used herein, when specific definition is not otherwise provided, “(meth)acrylate” refers to both “acrylate” and “methacrylate”, and “(meth)acrylic acid” refers to “acrylic acid” and “methacrylic acid.”

As used herein, when specific definition is not otherwise provided, the term “combination” refers to a mixture or a copolymerization.

As used herein, unless a specific definition is otherwise provided, a hydrogen atom is boned at the position when a chemical bond is not drawn where supposed to be given.

In the present specification, the term “semiconductor nanorod” refers to a rod-shaped semiconductor having a nano-sized diameter.

As used herein, when specific definition is not otherwise provided, indicates a point where the same or different atom or chemical formula is linked.

An ink composition for an electrophoresis apparatus according to an embodiment includes (A) a semiconductor nanorod; and (B) a compound represented by Chemical Formula 1.

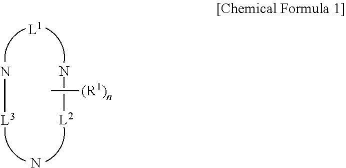

In Chemical Formula 1,

R¹ is a substituted or unsubstituted C1 to C20 alkyl group, a substituted or unsubstituted C1 to C20 alkoxy group, or a substituted or unsubstituted C6 to C20 aryl group,

L¹ to L³ are independently a substituted or unsubstituted C1 to C20 alkylene group, *—C(═O)—*, or *—C(R²)═*, wherein R² is a substituted or unsubstituted C1 to C10 alkyl group or a substituted or unsubstituted C1 to C10 alkoxy group, and

n is an integer of 0 to 3.

Recently, studies on various concepts having effects of improving energy efficiency and preventing efficiency drop of conventional LEDs such as micro LED, mini LED, and the like have been actively conducted. Among them, an alignment (electrophoresis) of InGaN-based nanorod LEDs using an electric field draws attentions as a method of dramatically reducing complex and expensive process costs of the micro LED, the mini LED, and the like.

Since the electrophoresis of nanorods is obtained by inkjetting or slit-coating nanorod dispersion, dispersion stability and dielectrophoretic properties of the nanorods in the solution are essential parameters for large area coating. The ink composition for an electrophoresis apparatus according to an embodiment may implement excellent dispersion stability and a high electrophoretic rate of InGaN-based or GaN-based nanorods. Specifically, a compound of a specific structure with high viscosity and a low dielectric constant may be used as a solvent to improve dispersibility and dispersion stability of the nanorods which are large and heavy and thus have high density and thus to accomplish excellent dielectrophoretic properties.

Hereinafter, each component is described in detail.

(A) Semiconductor Nanorod

The semiconductor nanorod may include a GaN-based compound, an InGaN-based compound, or a combination thereof, and the surface thereof may be coated with a metal oxide.

In order to secure dispersion stability of a semiconductor nanorod ink solution (semiconductor nanorod+solvent), it usually takes about 3 hours, which is insufficient time to perform a large area inkjet process. Accordingly, the inventions of the present invention have developed an insulating film (Al₂O₃ or SiOₓ) by coating a metal oxide such as alumina, silica, or a combination thereof on the surface of a semiconductor nanorod after numerous trial and error studies to maximize compatibility with a solvent described below.

For example, the insulating film coated with the metal oxide may have a thickness of 40 nm to 60 nm.

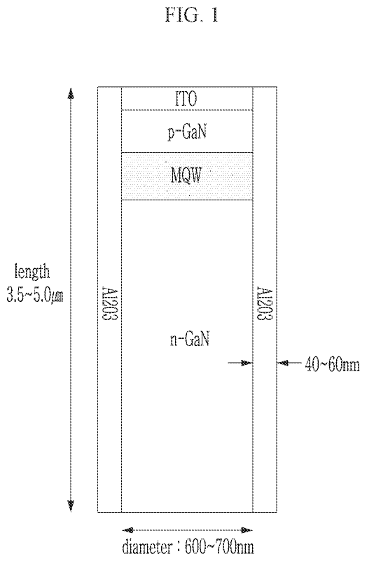

The semiconductor nanorod includes an n-type confinement layer and a p-type confinement layer, and a multi quantum well (MQW) active region active region may be disposed between the n-type confinement layer and the p-type confinement layer. (Refer to FIG. 1)

For example, the semiconductor nanorod may have a diameter of 300 nm to 900 nm, for example, 600 nm to 700 nm.

For example, the semiconductor nanorod may have a length of 3.5 μm to 5 μm.

For example, when the semiconductor nanorod may include an alumina insulating layer, it may have a density of 5 g/cm³ to 6 g/cm³.

For example, the semiconductor nanorod may have a mass of 1×10⁻¹³ g to 1×10⁻¹¹ g.

When the semiconductor nanorod has the above diameter, length, density and type, the surface coating of the metal oxide may be easily performed, so that dispersion stability of the semiconductor nanorods may be maximized.

The semiconductor nanorod may be included in an amount of 0.01 wt % to 10 wt %, for example 0.02 wt % to 8 wt %, for example 0.03 wt % to 5 wt %, based on a total amount of the ink composition. When the semiconductor nanorod is included within the above range, dispersibility in the ink is good, and the prepared pattern may have excellent luminance.

(B) Solvent

The ink composition for an electrophoresis apparatus according to an embodiment includes a solvent.

In recent years, as the needs for nano-scale micro LED devices are increasing, there has been an attempt to manufacture a nano-scale GaN-based or InGaN-based compound semiconductor as a rod, but a nanorod itself has a problem that dispersion stability in a solution (or a polymerizable compound) is greatly deteriorated. Until now, there has been no introduction of a technology of improving the dispersion stability of the semiconductor nanorods in a solution (or a polymerizable compound).

Organic solvents such as propylene glycol monomethyl ether acetate (PEGMEA), γ-butyrolactone (GBL), polyethylene glycol methyl ether (PGME), ethylacetate, isopropylalcohol (IPA), and the like, which have been used in conventional displays and electron materials have so low viscosity that inorganic material nanorod particles with high density are too fast sedimented, resulting in unsatisfactory dielectrophoretic properties. Accordingly, in order to develop NED-ink, a novel solvent having high viscosity and satisfactory dielectrophoretic properties and imparting sedimentation stability of the rods needs to be discovered.

The inventors of the present invention have developed a material structure with a high viscosity and a low dielectric constant instead of a conventional solvent with a low viscosity and thus accomplished excellent dispersion stability and a high electrophoretic rate of the semiconductor nanorods by using a solvent dispersing the semiconductor nanorods.

That is, as a solvent in the ink composition for an electrophoresis apparatus according to an embodiment, the compound represented by Chemical Formula 1 is included.

When the compound represented by Chemical Formula 1 is used as a solvent, dispersion stability of the semiconductor nanorods may be maximized and excellent dielectrophoretic properties may be realized.

For example, Chemical Formula 1 may be represented by Chemical Formula 2 or 3.

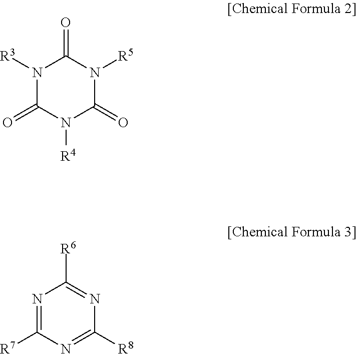

In Chemical Formula 2 and Chemical Formula 3,

R³ to R⁵ are independently a substituted or unsubstituted C1 to C20 alkyl group, and

R⁶ to R⁸ are independently a substituted or unsubstituted C1 to C20 alkoxy group.

For example, in Chemical Formula 2, R³ to R⁵ may independently be a C1 to C20 alkyl group unsubstituted or substituted with a C2 to C10 alkenyl group (e.g., vinyl group, etc.).

For example, in Chemical Formula 3, R⁶ to R⁸ may independently be a C1 to C20 alkoxy group unsubstituted or substituted with a C2 to C10 alkenyl group (e.g., a vinyl group, etc.).

For example, the compound represented by Chemical Formula 1 may include at least one selected from compounds represented by Chemical Formula 2-1, Chemical Formula 2-2, Chemical Formula 3-1, and Chemical Formula 3-2, but is not necessarily limited thereto.

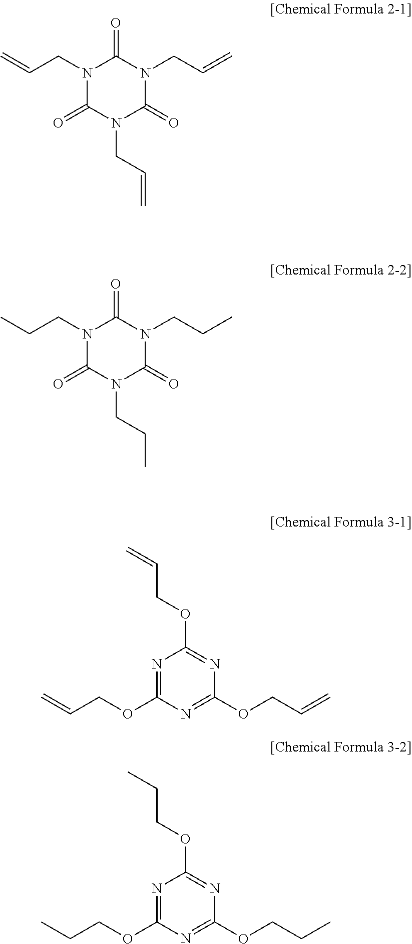

For example, The compound represented by Chemical Formula 1 has a viscosity at 25° C. of greater than or equal to 10 cps, for example, greater than or equal to 80 cps, for example greater than or equal to 100 cps, for example, 80 cps to 500 cps, for example, 100 cps to 500 cps, for example, 80 cps to 300 cps, for example 100 cps to 300 cps and a viscosity at 55° C. of 2 cps to 50 cps, for example, 6 cps to 20 cps, for example 7 cps to 20 cps, for example 10 cps to 20 cps. For example, a solid state may mean that the viscosity is infinite, and for example, a state in which a viscosity of greater than or equal to 10 cps may include a solid state. Since conventional organic solvents such as propylene glycol monomethyl ether acetate (PEGMEA), γ-butyrolactone (GBL), polyethylene glycol methyl ether (PGME), ethyl acetate, and isopropyl alcohol (IPA) have a low viscosity and high density, there is inevitably a limitation in improving the sedimentation stability of the semiconductor nanorods. However, since the compound represented by Chemical Formula 1 has a high viscosity, the sedimentation stability of the semiconductor nanorods having a high density may be remarkably improved.

Meanwhile, the compound represented by Chemical Formula 1 may have a dielectric constant of 2 to 8. All of the conventional organic solvents have high viscosity and high dielectric constant, so the dispersion stability of semiconductor nanorods is not good, and thus an electrophoretic rate is inevitably low. However, since the compound represented by Chemical Formula 1 has a dielectric constant, an electrophoretic rate may be greatly increased.

For example, the ink composition for an electrophoresis apparatus may further include a compound represented by Chemical Formula 4 in addition to the compound represented by Chemical Formula 1.

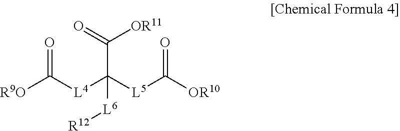

In Chemical Formula 4,

R⁹ to R¹¹ are independently a hydrogen atom or a C1 to C10 alkyl group,

R¹² is a hydrogen atom or *—C(═O)R¹³, wherein R¹³ is a C1 to C10 alkyl group,

L⁴ and L⁵ are independently a substituted or unsubstituted C1 to C20 alkylene group or a substituted or unsubstituted C6 to C20 arylene group, and

L⁶ is *—O—*, *—S—*, or *—NH—*.

For example, the compound represented by Chemical Formula 4 may be citric acid.

For example, the compound represented by Chemical Formula 4 may be represented by any one of Chemical Formula 4-1 to Chemical Formula 4-6, but is not necessarily limited thereto.

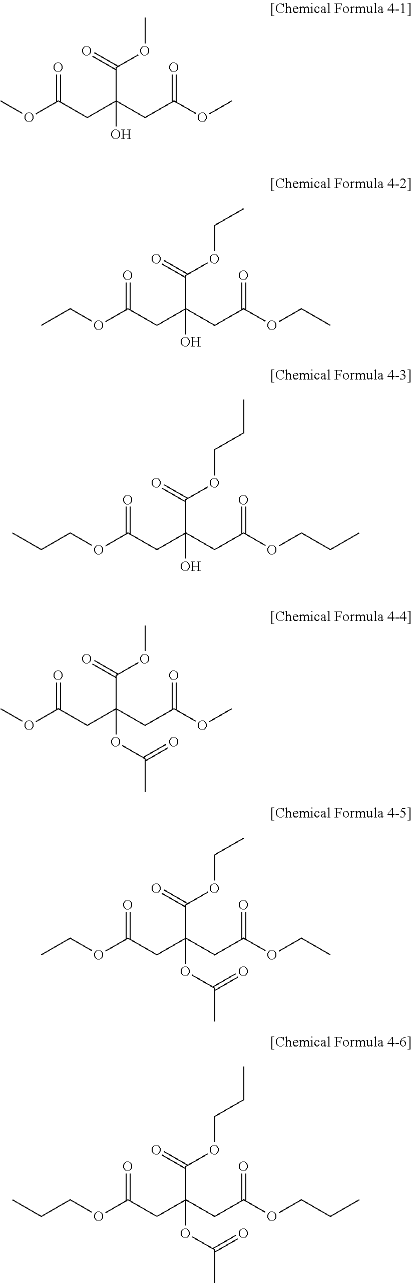

The solvent may be included in an amount of 30 wt % to 99.99 wt %, for example, 30 wt % to 95 wt %, for example 40 wt % to 90 wt % based on a total amount of the ink composition for an electrophoresis apparatus.

(C) Polymerizable Compound

The ink composition for an electrophoresis apparatus may further include a polymerizable compound having a carbon-carbon double bond at the terminal end.

The polymerizable compound may be used by mixing monomers or oligomers generally used in conventional curable ink compositions.

For example, the polymerizable compound may be a polymerizable monomer having at least one functional group represented by Chemical Formula 5-1 or a functional group represented by Chemical Formula 5-2 at the terminal end.

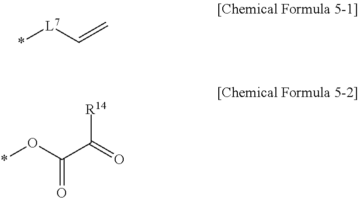

In Chemical Formula 5-1 and Chemical Formula 5-2,

L⁷ is a substituted or unsubstituted C1 to C20 alkylene group, and

R¹⁴ is a hydrogen atom or a substituted or unsubstituted C1 to C20 alkyl group.

The polymerizable compound forms a cross-linked structure with the semiconductor nanorod by including at least one carbon-carbon double bond at the terminal end, specifically at least one functional group represented by Chemical Formula 5-1 or a functional group represented by Chemical Formula 5-2 and thus dispersion stability of the semiconductor nanorods may be further improved.

For example, the polymerizable compound including at least one functional group represented by Chemical Formula 5-1 at the terminal end may be divinyl benzene, triallyl trimellitate, triallyl phosphate, triallyl phosphite, triallyl triazine, diallyl phthalate, or a combination thereof, but is not necessarily limited thereto.

For example, the polymerizable compound including at least one functional group represented by Chemical Formula 5-2 at the terminal end may be ethylene glycol diacrylate, triethylene glycol diacrylate, 1,4-butanediol diacrylate, 1,6-hexane diol diacrylate, neopentyl glycol diacrylate, pentaerythritol diacrylate, pentaerythritol triacrylate, dipentaerythritol diacrylate, dipentaerythritol triacrylate, dipentaerythritol pentaacrylate, pentaerythritol hexaacrylate, bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, 1,6-hexanediol dimethacrylate, polyfunctional epoxy (meth) acrylate, polyfunctional urethane (meth)acrylate, KAYARAD DPCA-20, KAYARAD DPCA-30, KAYARAD DPCA-60, KAYARAD DPCA-120, KAYARAD DPEA-12 of Nippon Chemical, or a combination thereof, but is not necessarily limited thereto.

(D) Polymerization Initiator

The ink composition for an electrophoresis apparatus according to an embodiment may further include a polymerization initiator, for example, a photopolymerization initiator, a thermal polymerization initiator, or a combination thereof.

The photopolymerization initiator may be an initiator generally used in curable ink compositions, for example, an acetophenone-based compound, a benzophenone-based compound, a thioxanthone-based compound, a benzoin-based compound, a triazine-based compound, an oxime-based compound, and an aminoketone-based compound, but is not necessarily limited thereto.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may include benzophenone, benzoyl benzoate, benzoyl methyl benzoate, 4-phenyl benzophenone, hydroxybenzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenonem, and the like.

Examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin-based compound may be benzoin, benzoin methyl ether, benzoin ethyl ether, benzoin isopropyl ether, benzoin isobutyl ether, benzyldimethylketal, and the like.

Examples of the triazine-based compound may be 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-trazine, 2-(p-methoxyphenyl)-4,6-bis(trichloromethyl)-s-triazine, 2-(p-tolyl)-4,6-bis(trichloro methyl)-s-triazine, 2-biphenyl-4,6-bis(trichloromethyl)-s-triazine, bis(tichloromethyl)-6-styryl-s-triazine, 2-(naphtho-1-yl)-4,6-bis(trchloromethyl)-s-triazine, 2-(4-methoxynaphtho-1-yl)-4,6-bis(trichloromethyl)-s-triazine, 2-4-bis(trichloromethyl)-6-piperonyl-s-trazine, 2-4-bis(trichloromethyl)-6-(4-methoxystyryl)-s-triazine, and the like.

Examples of the oxime compound may include an O-acyloxime compound, 2-(O-benzoyloxime)-1-[4-(phenylthio)phenyl]-1,2-octanedione, 1-(0-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Specific examples of the O-acyloxime-based compound may include 1,2-octanedione, 2-dimethylamino-2-(4-methylbenzyl)-1-(4-morpholin-4-yl-phenyl)-butane-1-one, 1-(4-phenylsulfanylphenyl)-butane-1,2-dione-2-oxime-O-benzoate, 1-(4-phenylsulfanylphenyl)-octane-1,2-dione-2-oxime-O-benzoate, 1-(4-phenylsulfanylphenyl)-octan-1-oneoxime-O-acetate, 1-(4-phenylsulfanylphenyl)-butan-1-oneoxime-O-acetate, and the like.

Examples of the aminoketone-based compound may include 2-benzyl-2-dimethylamino-1-(4-morpholinophenyl)-butanone-1.

The photopolymerization initiator may further include a carbazole-based compound, a diketone-based compound, a sulfonium borate-based compound, a diazo-based compound, an imidazole-based compound, a biimidazole-based compound, and the like, besides the compound.

The photopolymerization initiator may be used with a photosensitizer capable of causing a chemical reaction by absorbing light and becoming excited and then, transferring its energy.

Examples of the photosensitizer may be tetraethylene glycol bis-3-mercapto propionate, pentaerythritol tetrakis-3-mercapto propionate, dipentaerythritol tetrakis-3-mercapto propionate, and the like.

Examples of the thermal polymerization initiator may be peroxide, specifically, benzoyl peroxide, dibenzoyl peroxide, lauryl peroxide, dilauryl peroxide, di-tert-butyl peroxide, cyclohexane peroxide, methyl ethyl ketone peroxide, hydroperoxide (e.g., tert-butyl hydroperoxide, cumene hydroperoxide), dicyclohexyl peroxy dicarbonate, 2,2-azo-bis(isobutyronitrile), t-butyl perbenzoate, and the like and also, 2,2′-azobis-2-methylpropinonitrile and the like, but are not necessarily limited thereto and may include anything widely known in the related field.

The polymerization initiator may be included in an amount of 0.1 wt % to 10 wt %, for example, 0.5 wt % to 5 wt % based on a total amount of the ink composition for an electrophoresis apparatus. When the polymerization initiator is included within the ranges, the ink composition may be sufficiently cured during the exposure or thermal curing and thus obtain excellent reliability.

(E) Other Additives

The ink composition for an electrophoresis apparatus according to an embodiment may further include a polymerization inhibitor including a hydroquinone-based compound, a catechol-based compound, or a combination thereof. As the ink composition according to an embodiment further includes the hydroquinone-based compound, catechol-based compound, or combination thereof, after printing (coating) an ink composition, cross-linking at room temperature may be prevented during exposure.

For example, the hydroquinone-based compound, catechol-based compound, or combination thereof may include hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′) aluminium, or a combination thereof, but is not necessarily limited thereto.

The hydroquinone-based compound, catechol-based compound, or combination thereof may be used in a dispersion type and the dispersion-type polymerization inhibitor may be included in an amount of 0.001 wt % to 1 wt %, for example 0.01 wt % to 0.1 wt %, based on a total amount of the ink composition (regardless of solvent type or non-solvent type). When the stabilizer is included within the above range, the problem with aging at room temperature may be solved and sensitivity reduction and surface peeling may be prevented.

The ink composition for an electrophoresis apparatus according to an embodiment may further include malonic acid; 3-amino-1,2-propanediol; a silane-based coupling agent; a leveling agent; a fluorine-based surfactant; or combination thereof in addition to the polymerization inhibitor.

For example, the ink composition for an electrophoresis apparatus may further include a silane coupling agent having a reactive substituent such as a carboxyl group, a methacryloyl group, an isocyanate group, an epoxy group, and the like to improve its adherence to a substrate.

Examples of the silane-based coupling agent may include trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-epoxycyclohexylethyltrimethoxysilane, and the like. These may be used alone or in a mixture of two or more.

The silane-based coupling agent may be included in an amount of 0.01 parts by weight to 10 parts by weight based on 100 parts by weight of the ink composition for an electrophoresis apparatus. When the silane-coupling agent is included within the range, close contacting property, storing property, and the like may be improved.

In addition, the ink composition for an electrophoresis apparatus may further include a surfactant, for example a fluorine-based surfactant to improve coating and prevent a defect if necessary.

Examples of the fluorine-based surfactant may be BM-1000® and BM-1100® of BM Chemie Inc.; MEGAFACE F 142D®, MEGAFACE F 172®, MEGAFACE F 173®, and MEGAFACE F 183® of Dainippon Ink Kagaku Kogyo Co., Ltd.; FULORAD FC-135®, FULORAD FC-170C®, FULORAD FC-430®, and FULORAD FC-431® of Sumitomo 3M Co., Ltd.; SURFLON S-112®, SURFLON S-113®, SURFLON S-131®, SURFLON S-141®, and SURFLON S-145® of ASAHI Glass Co., Ltd.; and SH-28PA®, SH-190®, SH-193®, SZ-6032®, and SF-8428®, and the like of Toray Silicone Co., Ltd.; F-482, F-484, F-478, F-554, and the like of DIC Co., Ltd.

The fluorine-based surfactant may be included in an amount of 0.001 parts by weight to 5 parts by weight based on 100 parts by weight of the ink composition for an electrophoresis apparatus. When the fluorine-based surfactant is included within the above range, excellent wetting on a glass substrate as well as coating uniformity may be secured, and a stain may not be produced.

In addition, a certain amount of other additives such as antioxidants and stabilizers may be further added to the ink composition for an electrophoresis apparatus within a range that does not impair physical properties.

Binder Resin

The ink composition for an electrophoresis apparatus may further include a binder resin.

The binder resin may include an acryl-based binder resin, a cardo-based binder resin, or a combination thereof.

The acryl-based binder resin and cardo-based binder resin may be any known resin commonly used in a curable composition or a photosensitive composition, and the binder resin is not limited to a specific type.

The binder resin may be included in an amount of 1 wt % to 30 wt %, for example, 1 wt % to 20 wt % based on a total amount of an ink composition for an electrophoresis apparatus. When the binder resin is included within the above range, a curing shrinkage rate may be lowered.

Another embodiment provides a display device manufactured using the ink composition for an electrophoresis apparatus.

Hereinafter, examples of the present invention are described. These examples, however, are not in any sense to be interpreted as limiting the scope of the invention.

### (Preparation of Ink Composition for Electrophoresis Apparatus)

### Preparation of Solvent and Measurement of Viscosity and Dielectric Constant

Compound represented by Chemical Formula 2-1: 1,3,5-triallyl-1,3,5-triaone-2,4,6(1H,3H,51H)-trione (Sigma-Aldrich Corporation)
Compound represented by Chemical Formula 2-2:

1.8 g (15 mmol) of sodium p-toluene sulfinate was mixed with 300 ml of 1,3-dimethyl-2-imidazolidinone and 280 ml (3 mol) of propyl isocyanate and then, dried under a reduced pressure. A temperature of a flask was increased up to 80° C., and then, the obtained mixture was stirred for 24 hours. After cooling the flask down to 25° C., the resultant was purified to obtain a compound represented by Chemical Formula 2-2 by purifying N,N′,N″-isocyanurate through fractional distillation.
Compound represented by Chemical Formula 3-1: Triallyl cyanurate (Sigma-Aldrich Corporation)
Compound represented by Chemical Formula 3-2:

10 g (0.0543 mol) of cyanuric chloride and 10 g (0.178 mol) of propargyl alcohol were mixed with 250 ml of deionized water. 6 g (0.176 mol) of sodium hydroxide was added thereto at 25° C. and then, stirred for 2 hours. Subsequently, after increasing the temperature of the flask up to 50° C., the mixture was stirred for 7 hours. The reaction flask was cooled down to 25° C., and 100 ml of aq. saturated ammonium chloride was added thereto. The obtained mixture was transferred to a separatory funnel, and 150 ml of ethyl acetate was added thereto to extract the products. 300 ml (150 ml×2 times) of the ethyl acetate was used for additional extraction, and an organic layer collected therefrom was dried with magnesium sulfate. The ethyl acetate was removed therefrom through distillation under a reduced pressure after filtered with Celite 545 (Sigma-Aldrich Corporation). A product obtained therefrom was purified through fractional distillation to obtain a compound represented by Chemical Formula 3-2.
Compound represented by Chemical Formula 4-2: Triethyl citrate (Sigma-Aldrich Corporation)
Compound represented by Chemical Formula 4-4:

Citric acid (100 g, 0.5205 mol) was dissolved in 500 ml of methanol, and p-toluene sulfonic acid (0.99 g, 0.00521 mol) was added thereto and then, reacted for 12 hours under a reflux condition. After 12 hours, the solvent was removed therefrom by using a rotary evaporator, and 500 ml of ethyl acetate was added thereto. An organic layer produced therein was extracted and twice washed with 300 ml of an aq. 10% NaHCO₃ aqueous solution and additionally once washed with brine. Subsequently, the organic layer was dried with MgSO₄ and then, celite-filtered. After the filtering, the solvent was dried to obtain a compound represented by Chemical Formula 4-4 (trimethyl o-acetylcitrate).

A dielectric constant of the solvent was measured by using a liquid dielectric constant meter (10 KHz, Model 871 made by RUFUTO Co., Ltd.), viscosity was measured by using HAAKE RheoStress 6000 made by ThermoFisher Scientific, and the results are shown in Table 1.

### Examples 1 to 8 and Comparative Examples 1 to 4

A nanorod-patterned GaN wafer (4 inches) was reacted in 40 ml of stearic acid (1.5 mM) at room temperature (25° C.) for 24 hours. After the reaction, the nanorod-patterned GaN was dipped in 50 ml of acetone for 5 minutes to remove an excessive amount of the stearic acid, and additionally, 40 ml of acetone was used to rinse the surface of the wafer. The washed wafer was put with 35 ml of GBL in a 27 kW bath-type sonicator and then, sonicated for 5 minutes to separate the rod from the wafer surface. The separated rod was put in a FALCON tube for a centrifuge, and 10 ml of GBL was added thereto to additionally wash the rod on the bath surface. Then, a supernatant was discarded therefrom through centrifugation at 4000 rpm for 10 minutes, and precipitates therein were redispersed in 40 ml of acetone and filtered with a 10 μm mesh filter. After additional centrifugation (4000 rpm, 10 minutes), the precipitates were dried in a drying oven (100° C., 1 hour), and the weight was measured, and then, the resultants were dispersed to be 0.2 w/w % in a solvent shown in Table 1, to prepare ink compositions.

TABLE 1

| | | Solvent viscosity | Solvent |
|---|---|---|---|
| | | (cps) | dielectric |
| | Solvent | (25° C./55° C.) | constant |
| Example 1 | Chemical Formula 2-1 | 144/17 | 2.7 |
| Example 2 | Chemical Formula 2-2 | 116/13.2 | 2.5 |
| Example 3 | Chemical Formula 3-1 | Solid/7.2 | 2.6 |
| Example 4 | Chemical Formula 3-2 | 84/6.5 | 2.6 |
| Example 5 | (Chemical Formula 2-1) + | 88/15 | 7.0 |
| | (Chemical Formula 4-4) + | | |
| | (Chemical Formula 4-2) | | |
| Example 6 | (Chemical Formula 2-2) + | 84/15 | 6.9 |
| | (Chemical Formula 4-4) + | | |
| | (Chemical Formula 4-2) | | |
| Example 7 | (Chemical Formula 3-1) + | 81/15 | 6.6 |
| | (Chemical Formula 4-4) + | | |
| | (Chemical Formula 4-2) | | |
| Example 8 | (Chemical Formula 3-2) + | 82/15 | 6.5 |
| | (Chemical Formula 4-4) + | | |
| | (Chemical Formula 4-2) | | |
| Comparative | PGMEA | 0.8/— | 8.2 |
| Example 1 | | | |
| Comparative | GBL | 1.7/— | 42.8 |
| Example 2 | | | |
| Comparative | Chemical Formula 4-4 | 354/31 | 9.6 |
| Example 3 | | | |
| Comparative | Chemical Formula 4-2 | 30/7.7 | 11 |
| Example 4 | | | |

(As for PGMEA and GBL, viscosity was too low at 55° C. to be measured)

### Evaluation: Sedimentation Rate and Dielectrophoretic Properties of Ink Compositions

The ink compositions according to Examples 1 to 8 and Comparative Examples 1 to 4 were measured with respect to sedimentation rates and dielectrophoretic properties using Turbiscan, and the results are shown in Table 2.

The dielectrophoretic properties were measured in the following method.

First, 500 μl of each nanorod ink compositions was coated on a thin-film gold basic interdigitated linear electrode (ED-cIDE4-Au, Micrux Technologies) and after applying an electric field (25 KHz, ±30 v) thereto, waited for 1 minute. Subsequently, a hot plate was used to dry the solvent, and a microscope was used to count the number of aligned ones (ea.) and the number unaligned ones (ea.) in the center between the electrodes and thus evaluate dielectrophoretic properties.

TABLE 2

| | | | | | | | | | Comp. | Comp. | Comp. | Comp. |
|---|---|---|---|---|---|---|---|---|---|---|---|---|
| | Ex. 1 | Ex. 2 | Ex. 3 | Ex. 4 | Ex. 5 | Ex. 6 | Ex. 7 | Ex. 8 | Ex. 1 | Ex. 2 | Ex. 3 | Ex. 4 |
| Sedimentation | 0.052 | 0.068 | — | 0.081 | 0.079 | 0.081 | 0.082 | 0.082 | 0.95 | 0.91 | 0.012 | 0.20 |
| rate (mm/hr) | | | | | | | | | | | | |
| Dielectrophoretic | 56 | 65 | 38 | 48 | 94 | 92 | 91 | 93 | 74 | 38 | 84 | 92 |
| properties (%) | | | | | | | | | | | | |

As shown in Table 1, Examples 1 to 8 exhibited low sedimentation rates and simultaneously, excellent dielectrophoretic properties, compared with Comparative Examples 1 to 4, and accordingly, the ink compositions for an electrophoresis apparatus according to an embodiment greatly improved dispersion stability of semiconductor nanorods and simultaneously, had very excellent dielectrophoretic properties and thus may be suitable for large area coating and panel production.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

1. An ink composition for an electrophoresis apparatus, comprising:
(A) a semiconductor nanorod; and
(B) a compound represented by Chemical Formula 1: 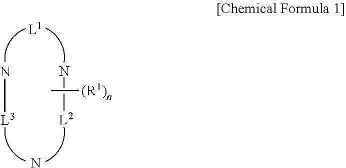
wherein, in Chemical Formula 1,
R¹ is a substituted or unsubstituted C1 to C20 alkyl group, a substituted or unsubstituted C1 to C20 alkoxy group, or a substituted or unsubstituted C6 to C20 aryl group,
L¹ to L³ are independently a substituted or unsubstituted C1 to C20 alkylene group, *—C(═O)—*, or *—C(R²)═*, wherein R² is a substituted or unsubstituted C1 to C10 alkyl group or a substituted or unsubstituted C1 to C10 alkoxy group, and
n is an integer of 0 to 3.

2. The ink composition of claim 1, wherein Chemical Formula 1 is represented by Chemical Formula 2 or Chemical Formula 3: 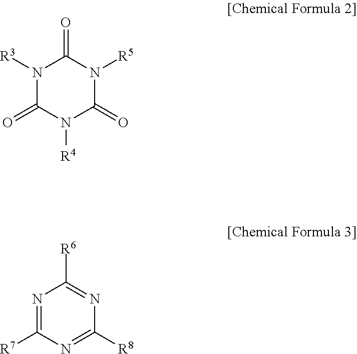
wherein, in Chemical Formula 2 and Chemical Formula 3,
R³ to R⁵ are independently a substituted or unsubstituted C1 to C20 alkyl group, and
R⁶ to R⁸ are independently a substituted or unsubstituted C1 to C20 alkoxy group.

3. The ink composition of claim 2, wherein
R³ to R⁵ are independently a C1 to C20 alkyl group that is substituted or unsubstituted with a C2 to C10 alkenyl group, and
R⁶ to R⁸ are independently a C1 to C20 alkoxy group that is substituted or unsubstituted with a C2 to C10 alkenyl group.

4. The ink composition of claim 1, wherein the compound represented by Chemical Formula 1 includes at least one selected from compounds represented by Chemical Formula 2-1, Chemical Formula 2-2, Chemical Formula 3-1, and Chemical Formula 3-2:

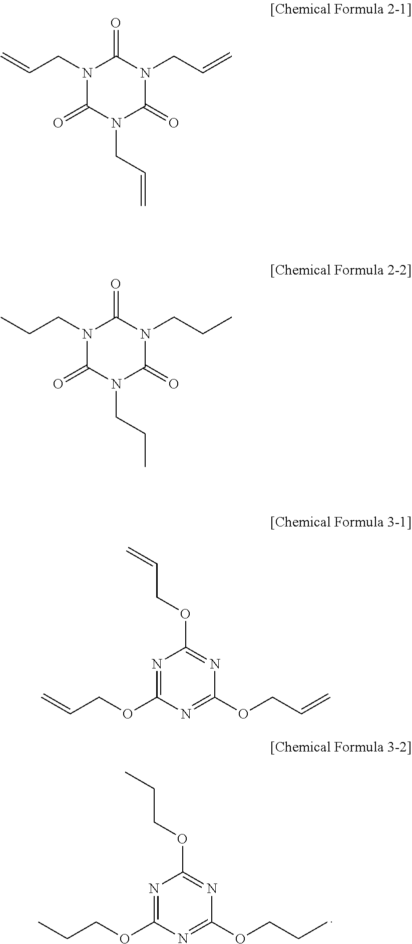

5. The ink composition of claim 1, wherein the compound represented by Chemical Formula 1 has a viscosity of greater than or equal to 10 cps at 25° C.

6. The ink composition of claim 1, wherein the compound represented by Chemical Formula 1 has a viscosity of 80 cps to 500 cps at 25° C.

7. The ink composition of claim 1, wherein the compound represented by Chemical Formula 1 has a viscosity of 10 cps to 20 cps at 55° C.

8. The ink composition of claim 1, wherein the compound represented by Chemical Formula 1 has a dielectric constant of 2 to 8.

9. The ink composition of claim 1, wherein the ink composition for the electrophoresis apparatus further includes a compound represented by Chemical Formula 4. 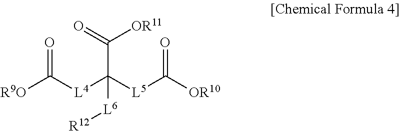
wherein, in Chemical Formula 4,
R⁹ to R¹¹ are independently a hydrogen atom or a C1 to C10 alkyl group,
R¹² is a hydrogen atom or *—C(═O)R¹³, wherein R¹³ is a C1 to C10 alkyl group,
L⁴ and L⁵ are independently a substituted or unsubstituted C1 to C20 alkylene group or a substituted or unsubstituted C6 to C20 arylene group, and
L⁶ is *—O—*, *—S—*, or *—NH—*.

10. The ink composition of claim 1, wherein the semiconductor nanorod has a diameter of 300 nm to 900 nm.

11. The ink composition of claim 1, wherein the semiconductor nanorod has a length of 3.5 μm to 5 μm.

12. The ink composition of claim 1, wherein the semiconductor nanorod includes a GaN-based compound, an InGaN-based compound, or a combination thereof.

13. The ink composition of claim 1, wherein the semiconductor nanorod has a surface coated with a metal oxide.

14. The ink composition of claim 13, wherein the metal oxide includes alumina, silica, or a combination thereof.

15. The ink composition of claim 1, wherein the semiconductor nanorod is included in an amount of 0.01 wt % to 10 wt % based on a total amount of the ink composition for the electrophoresis apparatus.

16. The ink composition of claim 1, wherein the semiconductor nanorod further includes a polymerizable compound.

17. The ink composition of claim 1, wherein the ink composition for the electrophoresis apparatus further includes malonic acid; 3-amino-1,2-propanediol; a silane coupling agent; a leveling agent; a fluorine-based surfactant; or a combination thereof.

18. A display device manufactured using the ink composition for the electrophoresis apparatus of claim 1.
